(19) United States
(12) Patent Application Publication
(10) Pub. No.: US 2002/0070411 A1
(43) Pub. Date: Jun. 13, 2002

(54) Method of processing a high voltage p++/n-well junction and a device manufactured by the method

(75) Inventors: Miguel Vermandel, Sijsele (BE); Andre Van Calster, Heusden (BE); Peter Moens, Zottegem (BE); Hugo Van Hove, Maarkedal (BE); Marnix Tack, Merelbeke (BE)

Correspondence Address: KNOBBE MARTENS OLSON & BEAR LLP, 620 NEWPORT CENTER DRIVE, SIXTEENTH FLOOR, NEWPORT BEACH, CA, 92660, US

(73) Assignee: Alcatel

(21) Appl. No.: 09/950,835

(22) Filed: Sep. 10, 2001

Related U.S. Application Data
(60) Provisional application No. 60/231,467, filed on Sep. 8, 2000.

(51) Int. Cl. H01L 31/119; H01L 31/113; H01L 31/062; H01L 29/94; H01L 29/76

(52) U.S. Cl. 257/371

(57) ABSTRACT

The present invention is related to a method of processing a high voltage p++/n-well junction on a substrate comprising at least one n-well region and at least one p-well region. The method comprises performing a p-type implantation in a zone surrounding said high voltage p++/n-well junction independently from other implantation.

### RELATED APPLICATIONS

This application claims priority under 35 U.S.C. §119(e) from U.S. Provisional Patent Application No. 60/231,467, filed Sept. 8, 2000.

### BACKGROUND OF THE INVENTION

1. Field of the Invention

The present invention is related to a high voltage p++/n-well junction in a standard submicron CMOS technology, more particularly to a method of providing a p-type implantation, independently from other type implantations, around a high voltage p++/n-well junction, such as a P-Drain Extended MOS (PDEMOS) or high voltage diode.

2. Description of the Related Technology

High voltage p++/n-well junctions in standard CMOS technologies are well known in such applications as a high voltage PDEMOS or a high voltage floating p++/n-well diode. A PDEMOS device is described in ‘A High Voltage p-type Drain Extended MOS in a Low Voltage Sub-micron CMOS Technology’, Vermandel et al., ESSDERC, 1998, p. 492-495, which is hereby incorporated by reference. The device described in Vermandel has a lowly doped p-type implant underneath the field oxide of the PDEMOS. The p-type implant acts as a ‘drift region’ and substantially coincides with the surface of the field oxide. This gives the advantage of producing a self-aligned p-type implant, facilitating the design of such a device. Moreover, Vermandel suggests a method in which this type of p-type implant is performed simultaneously with the other p-field implants underneath the field oxide in the adjacent p-well regions. The latter types of implants have a different function from the former one, namely they suppress the operation of so-called parasitic field transistors in the vicinity of the field oxide in the p-well regions. Vermandel discloses that it has an advantage of creating the implants in the same processing step, since both implants are of the same type. However, the different function of both implants raises some problems, which are acknowledged by Vermandel.

A study has been continued to solve the problems, which results in the influence of some process parameters on the characteristics of both types of implants. In addition, optimizing the p-type implant underneath the PDEMOS-field oxide will also influence the ordinary transistors (e.g. effective width) and the parasitic field transistors (e.g. threshold voltage) in the p-well region in an unintended way.

In the design of PDEMOS devices, another type of implant has been described in ‘High Voltage CMOS LCD Driver Using Low Voltage CMOS process’, J. Haas et al., CICC'89, p. 14.6.1-14.6.4. J. Haas discloses that a p-implant is applied underneath the p++/n-well junction in order to achieve a smoother gradient of the junction, augmenting its breakdown voltage. A problem in this design is that it does not allow a self-aligned implant.

FIG. 1 represents a PDEMOS device according to a conventional method. The PDEMOS includes a source 41, a drain 43, a field oxide 44, a gate 45 and a p-type implant 46. In General CMOS technology, a substrate is divided into a number of n-well regions and p-well regions. However, only an n-well region 40 and a p-well region 50 are shown on a low doped p-substrate 39, in FIG. 1. The n-well and p-well regions 40 and 50 are doped with e.g. Phosphorus and Boron atoms, respectively. An active area 51 that contains transistors or diodes is then created on the n-well and p-well regions 40 and 50, though it is shown only on the p-well region 50 in FIG. 1. The active areas are separated by field oxides 52. A low doped p-field implant 53 is normally applied underneath the field oxides 52 in the p-well region 50, in order to enhance the threshold voltage of the parasitic transistors (not shown) which are inherently created with the field oxides 52. In the n-well region 40, normally, a p-type implant 46 is not applied underneath the field oxide 44. However, the p-type implant 46 is applied underneath the field oxide 44 of a high voltage transistor, such as the PDEMOS, in FIG. 1.

In this last case, the p-type implant 46 does not serve to increase the threshold voltage but serves as a drift region with a constant resistance, thereby extending the drain 43 to the channel and allowing the high voltage device to function properly.

However, the p-type implant 46 and the p-field implant 53 in FIG. 1 are implanted in the same step, using one mask, thereby diminishing the capability of optimizing the characteristics of the implant near the high voltage junction. Also, the p-type implant 46 might have an insufficient doping level, leading to a bad connection between the implant 46 and the drain 43. Moreover, the effective width of the nMOS transistors in the p-well region 50 may be badly affected.

### SUMMARY OF CERTAIN INVENTIVE ASPECTS

The present invention provides a method of processing a high voltage p++/n-well junction, with a high breakdown voltage, said method allowing the application of a self-aligned p-type implant.

The present invention also provides a device comprising such a high voltage p++/n-well junction, manufactured by the method.

One aspect of the present invention is to provide a method of processing at least one high voltage p++/n-well junction on a substrate comprising at least one n-well region and at least one p-well region. The method comprises performing a p-type implantation in a zone surrounding said high voltage p++/n-well junction independently from other implantation.

Another aspect of the present invention is to provide a method of processing at least one high voltage p++/n-well junction on a substrate comprising at least one n-well region and at least one p-well region. The method comprises performing a first implantation for a p-field implant in said p-well region as well as a p-type implant around said high voltage p++/n-well junction in said n-well region, and performing a second implantation independently from the first implantation for said p-type implant around said high voltage junction in said n-well region, so as to modify the characteristics of said p-type implant in said n-well region, independently from those of said p-field implant in said p-well region.

Another aspect of the present invention is to provide a method of processing at least one high voltage p++/n-well junction on a substrate comprising at least one n-well region and at least one p-well region. The method comprises performing a first implantation for a p-field implant in said p-well region, and performing a second implantation independently from the first implantation for said p-type implant around said high voltage junction in said n-well region.

Still, another aspect of the present invention is to provide a method of processing at least one high voltage p++/n-well junction on a substrate comprising at least one n-well region and at least one p-well region. The method comprises performing a first implantation for a p-field implant in said p-well region, growing a field oxide in said n-well region, and performing a second implantation independently from the first implantation through the field oxide for said p-type implant around said high voltage junction in said n-well region.

### BRIEF DESCRIPTION OF THE DRAWINGS

FIG. 1 represents a PDEMOS device, according to the prior art.

FIG. 2 represents a typical basic structure of the high voltage p++/n-well junction without p-type implants.

FIG. 3 represents a typical structure of the high voltage p++/n-well junction with p-type implants.

FIGS. 4 and 5 illustrate the influence of the n-well/p-substrate junction.

FIG. 6 illustrates the influence of the width of the p++region.

FIG. 7 illustrates the influence of the width of the p++region on the breakdown voltage.

FIG. 8 illustrates the influence of the implant dose and anneal time of the p-type implant on the breakdown voltage.

FIG. 9 represents a PDEMOS device according to the present invention.

FIG. 10 illustrates a simulation of the influence of the p++region width on the breakdown voltage.

FIG. 11 illustrates a simulation of the influence of the p-type implant depth on the breakdown voltage.

FIG. 12 illustrates a simulation of the influence of the p-type implant width on the breakdown voltage.

FIG. 13 illustrates the influence of the width of the p-type implant for different implant doses.

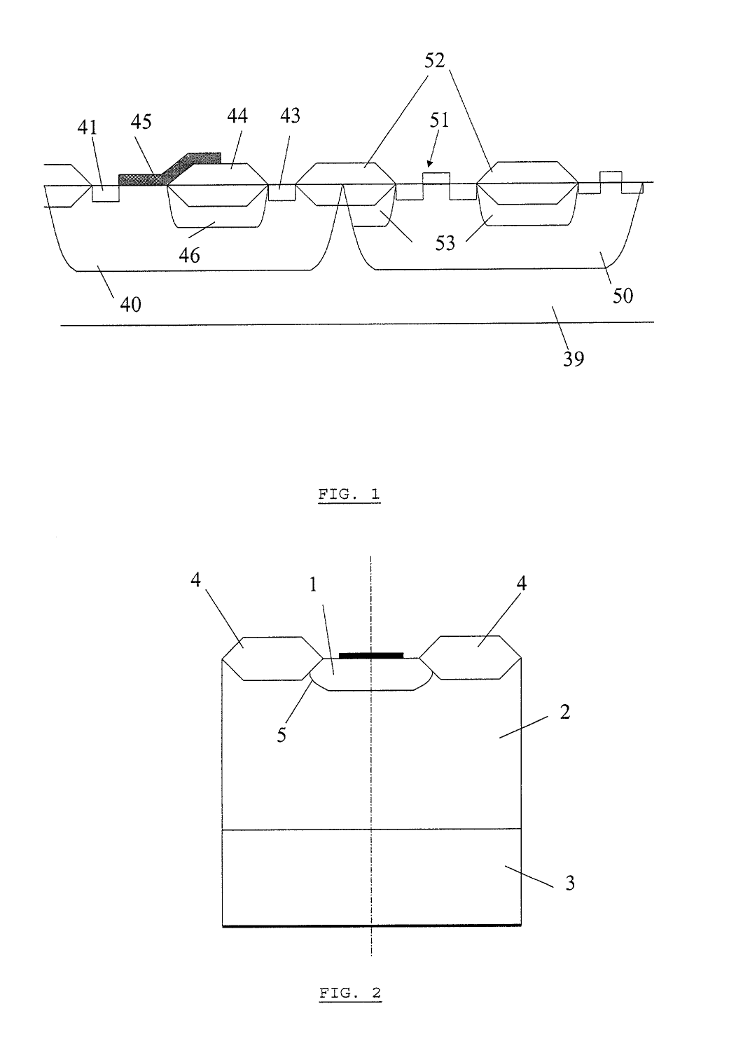

### DETAILED DESCRIPTION OF CERTAIN INVENTIVE EMBODIMENTS

In one aspect, the present invention includes a processing method which allows the optimization of the characteristics of the p-type implant around the high voltage junction. Furthermore, the present invention may produce high voltage p++/n-well junctions with improved breakdown behavior owing to the independent modification of the characteristics of the p-type implants.

Using the present invention allows the external applied voltages of an integrated circuit to be on the order of 80V, preferably 70V, and more preferably 60V. With reference to FIG. 9, several embodiments of the invention will be explained.

A first embodiment according to the invention comprises the following steps:

defining the active area 51 on both the n-well and the p-well regions 40 and 50 on the substrate 39, wherein defining the active area 51 means covering the active area 51 by a mask (not shown), whereby the active areas are covered by a nitride layer (not shown), which protects the area 51 from the following implantation steps,

in a first implantation step, implanting the p-field implant 53 in the p-well region 50, e.g. with Boron (B) or BF2 as well as in some area of the n-well region 40, e.g. the location of the field oxide 44 in high voltage device such as a PDEMOS,

in a second, separate implantation step from the first one, implanting the p-type implant 46 in the n-well region 40, e.g. with B or BF2, to modify the characteristics of the p-type implant 46, independently from the p-field implant 53 in the p-well region 50,

and growing the field oxides 44 and 52, and further processing the active area 51.

The third step (implanting the p-type implant 46 in the n-well region 40) requires an additional mask and an additional implantation step compared with the conventional method described above, but gives the advantage that the characteristics of the p-type implant 46 in the n-well region 40 (in high voltage devices) can be tuned without influencing the ordinary transistors (not shown) in the p-well region 50.

The first embodiment is especially suited for cases wherein each of the p-type implants is coinciding with each of the field oxides, so that self-aligned p-type implants are produced.

A second embodiment according to the present invention comprises the following steps:

defining the active area 51 on both the n-well and the p-well regions 40 and 50 on the substrate 39,

in a first implantation step, implanting the p-field implant 53 in the p-well region 50,

in a second, separate implantation step from the first one, implanting the p-type implant 46 in the n-well region 40, independently from the p-field implant 53 in the p-well region 50,

and growing the field oxides 44 and 52, and further processing the active area 51.

This embodiment also requires an additional mask and an additional implantation step compared with the conventional method described above. However, now the creation of the p-type implant 46 in the n-well region 40 is done totally independently from the p-field implant 53 in the p-well region 50.

In the second embodiment, the p-type implant 46 may be spatially coincident with the surface of the field oxide 44, either wholly (self-aligned implants) or partially. If p-type implant 46 is done independently of the p-field implant 53 and after the growth of the field oxide 44, one has total freedom about the location of the implant. This location depends on where the structures are defined. If the implant 46, whether or not independent from implant 53, is done prior to growing the field oxide 44 (this may be done together with the field oxide 52, then the implant 46 is self-aligned to the field oxide 44 or consequently to the active area 43 which is the inverse of the field region.

For example, it can be advantageous to have the p-type implant 46 surrounding a high voltage p++/n-well junction in its immediate vicinity, which may be the case for high voltage diodes.

In a third embodiment of the present invention, the implantation of the p-type implant 46 around the high voltage junction is done after the growing of the field oxide 44 This means that the implant 46 is created through this field oxide 44. In this case higher energies are required (range 150-300 keV for a B implant to allow implantation of the p-type implant 46 through the field oxide 44 thus doping the region underneath the field oxide 44. The choice between B or BF2 depends only on the as-implanted effective energy which is function of the mass of the implant species (B-part of the BF2) and the energy given to this species. This embodiment has the advantage that during the growth of the field oxide 44, no dopants already present at the field oxides 44 and 52 are being absorbed by the field oxide leading to a smaller effective doping of the p-type and p-field implants 46 and 53. The implantation dose of the separate implantation step according to the third embodiment preferably lies between 5×1011/cm2 and 1×1013/cm2.

The nitride covering of the active areas 41, 43 and 51 will prevent the active areas 41, 43 and 51 from being doped by the implantation of the p-type implant 46 in the third embodiment, while the implantation can still get through the field oxide 44.

All three embodiments are characterized by the fact that a separate implantation step is performed, wherein the p-type implant 46 in the immediate vicinity of the high voltage p++/n-well junction is produced.

Both the first and second embodiments comprise additional steps. The third embodiment might need an additional step, but again one can decide whether implant 46 is done together with 53 or whether implant 46 is done independently from implant 53. In the independent implant option, an additional masking step is needed to define the implant region 46. However, the independent implant only is relevant to the present invention. Steps not mentioned above are printing steps, cleaning steps, annealing steps, etc. However, since those steps are well known to a skilled technologist, their description will be omitted.

Since in the above-described method, all implantation steps are performed after the definition of the active area 51, there is no possibility of having such a p-type implant 46 extending under the p++ region of a high voltage p++/n-well junction, as described in the prior art. On the other hand, in the prior art, the n-well 40 and p-well 50 are created prior to active area definition. Also, implants 46 and 53 may be created prior to defining the active areas 41, 43 and 51, but this is not self-aligned.

However, the present invention does allow one to produce such a high voltage junction, surrounded by one or more p-type implants of which the characteristics can be tuned at will. In the following description, by referring to FIGS. 2-8 and 10-13, it will be shown that this feature allows one to increase the breakdown voltage of the junction accordingly, thereby avoiding the need for the ‘intermediate’ p-type implant described by Haas et al.

FIG. 2 shows a typical structure of a high voltage p++/n-well junction without p-type implants. The structure comprises a highly doped p++ region 1 in a low-doped n-layer 2, the n-well, placed on a low-doped p-substrate 3. The p++ region 1 might represent the drain of a PDEMOS transistor which is put at the same negative voltage as the p-substrate 3, with respect to the n-well 2. A layer of field oxide 4 surrounds the p++ region 1. The p++/n-well junction must remain reverse-biased at all times. Breakdown will occur at the vertical p++/n-well junction, underneath the bird's beak 5, due to the sharp curvature of the junction there.

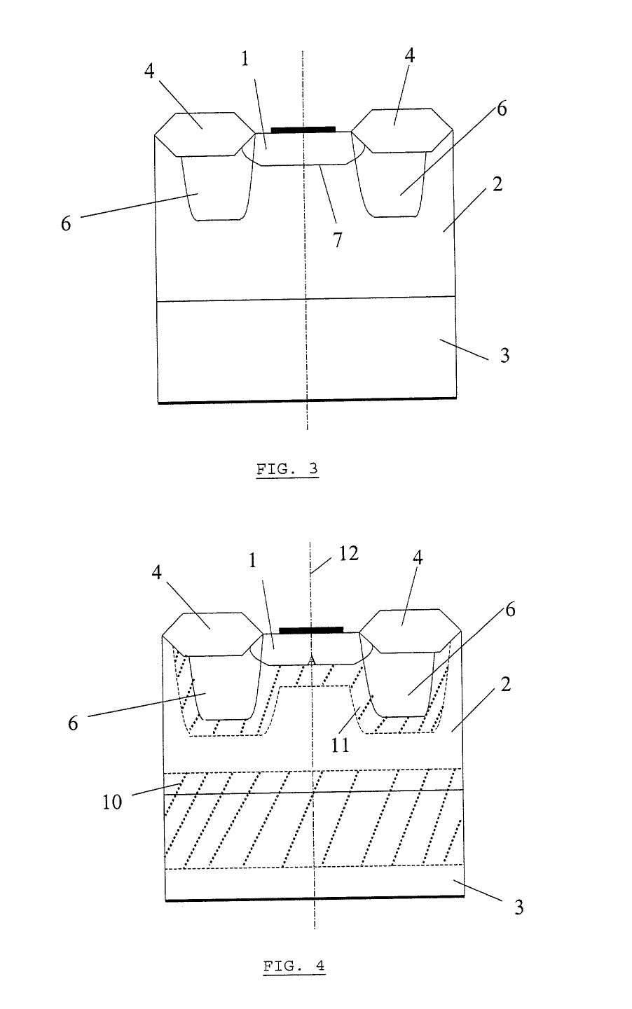

FIG. 3 illustrates the same structure as FIG. 2, except for the low doped p-type implant 6 around the p++ region 1. The p-type implant 6 may be spatially coincident with the surface of the field oxide 4, either wholly or partially as discussed above. It is assumed that the p-type implant 6 surrounds the p++ region 1 in all directions. If one of the embodiments according to the invention is applied, the p-type implant 6 may not extend beyond the field oxide 4, i.e. under the active area (not shown). This is because the p-type implant 6 is created after the definition of the active areas. Still, the p-type implant 6 according to the invention has a beneficial influence on the p++/n-well junction. One of these benefits is that the breakdown region is shifted to the horizontal part 7 of the p++/n-well junction. This leads to an increase in the breakdown voltage. Depending on the width of the p++ region 1, the dose and depth of the p-implant 6, and the depth of the n-well 2, two different phenomena will further increase the breakdown voltage.

1. The influence of the n-well/p-substrate junction (FIGS. 4 and 5)

FIG. 4 shows a depletion area 10 around the n-well 2/p-substrate 3 junction and a depletion area 11 around the n-well 2/(p++ 1 and p- 6 implant junction.

In FIG. 4, both of the depletion areas 10 and 11 are separated. This means that the breakdown voltage is mainly determined by the horizontal p++ 1/n-well 2 junction 11.

FIG. 5 shows the case where both areas 10 and 11 reach each other, leaving the new p++ 1/n-well 2 junction 13, which includes the depletion area 10 (FIG. 4), isolated from the rest of the n-well region 2. This must happen when a high voltage applies to the device. That is, the p++/n-well junction 13 is separated from the rest 2 of the n-well region at the bottom by the depletion area 10, and at the side by the p-type implant 6. The result is that the vertical potential drop along the cut line 12 is not as high, reducing the electric field far below the critical value. Therefore, a much higher voltage can be applied to the n-well region 2 before breakdown occurs.

The effect illustrated in FIG. 5 is dependent on the doping levels of the n-well region 2 and on the depth and the doping levels of the p-type implant 6. Since the present invention offers a method in which the p-type implant characteristics can be optimized without badly affecting the operation of the ordinary transistors in the p-well region, this effect can be more easily obtained by using the separate implantation step described in the embodiments of the present invention.

2. The influence of the p++ region

For a wide p++ region 1 (FIG. 3), the vertical depletion of the p-implant 6 underneath the field oxide 4 does not influence the horizontal p++/n-well junction.

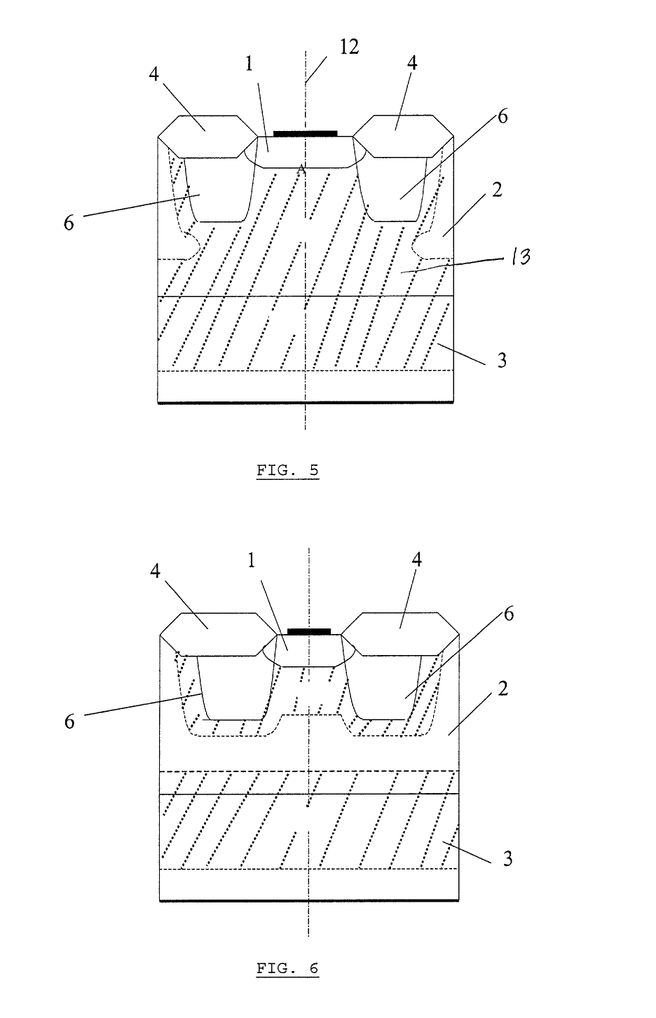

For a less wide p++ region 1, the effect shown in FIG. 6 becomes apparent.

The depletion of the vertical junction of the p-type implant 6 underneath the field oxide 4 starts to reinforce the depletion of the horizontal p++ implant. For the same applied voltage, the potential lines are more vertically stretched into the n-well region 2, resulting in a lower electric field. This results in the necessity of a higher voltage to reach the critical electric field and breakdown.

The effect illustrated in FIG. 6 may also be enhanced by the method of the invention, which allows the optimized tuning of the doping level of the p-type implant 6, which is related to the thickness of the depletion zones.

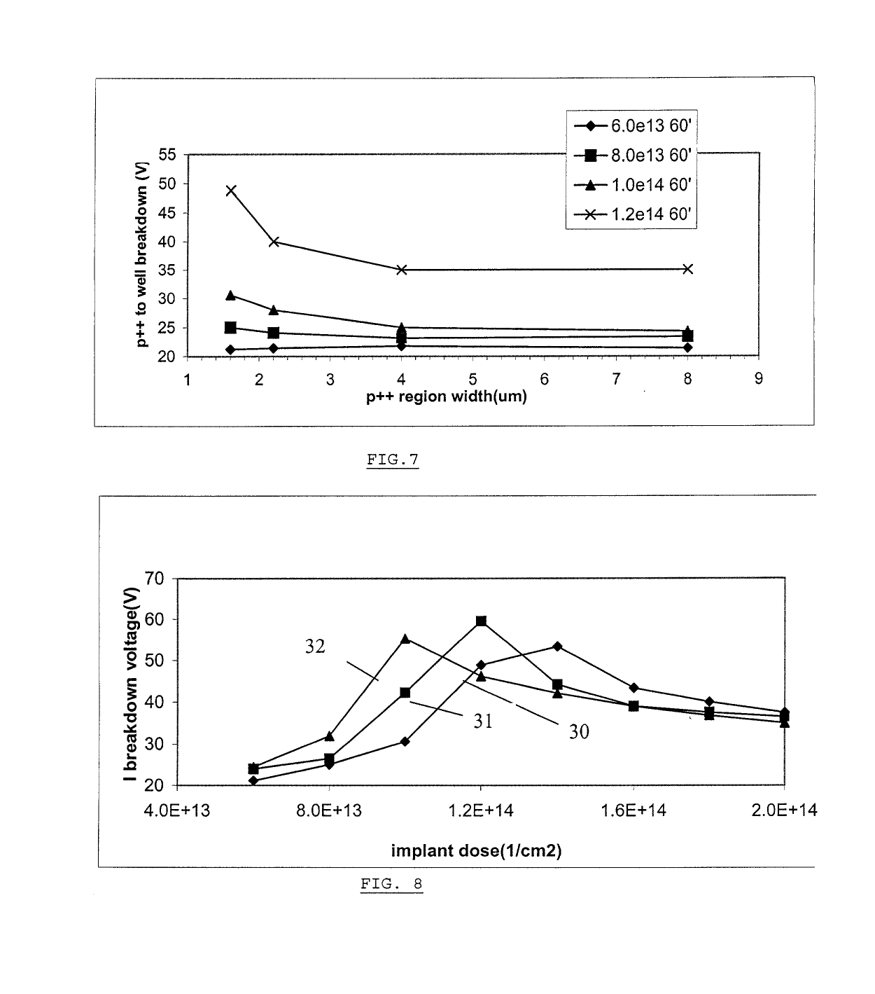

The active area definition width of the p++ regions (i.e. as designed) in high voltage devices according to the present invention, lies between 1.6 m and 8 m, with the smaller values enhancing the effect described above, as can be seen in FIG. 7, for different values of the implantation dose of the separate implantation step. As explained in the discussion of FIGS. 4-6, the depth and the doping level of the separate p-type implant 6 are determining the eventual breakdown voltage of the p++/n-well junction. These parameters are depending on the process parameters with which the p-type implant 6 has been created. These parameters comprise an implantation dose, an implantation energy, an anneal time and an anneal temperature. The annealing is a necessary step after any implantation step.

A prior research has searched for those processing characteristics of the p-type implants which influenced the implants in the n-well region (high voltage device) in a positive way, while influencing as little as possible the implants in the p-well region. As a result, it has been found that the implant dose and the anneal time among the parameters have the least influence on the ordinary MOS devices and are therefore most suited in order to optimize the p-type implants next to high voltage junctions in the n-well region. However, With the method of the present invention, since the p-type implants in the n-well and p-well regions can be tuned independently, other parameters (e.g. anneal temperature, implantation energy) besides the implant dose and the anneal time may be regarded as useful to optimize the high voltage p-type implant.

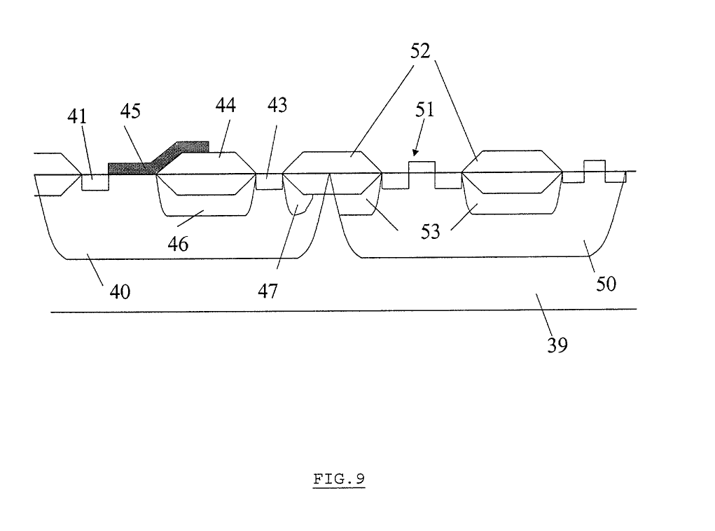

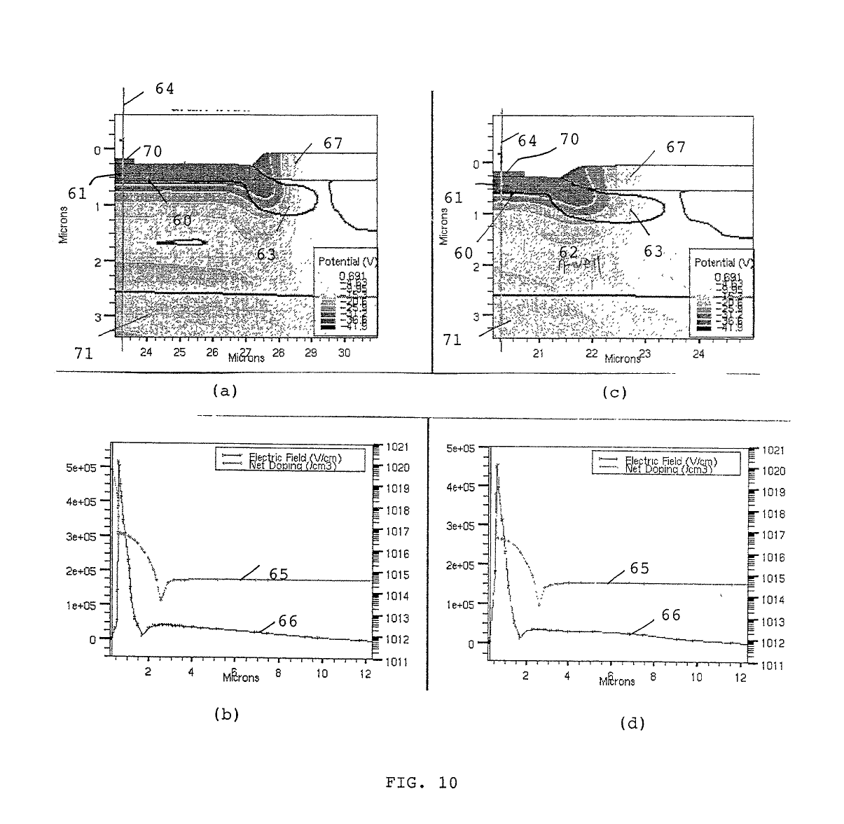

FIG. 8 shows a graph wherein the effect on the breakdown voltage of the doping level and of the anneal time of the separate p-type implant in the n-well region. A Curve 30 shows the breakdown voltage as a function of p-implant implantation dose for an anneal time of 60 minutes. A Curve 31 shows the same for an anneal time of 90 minutes. A Curve 32 corresponds to an anneal time of 120 minutes. Each of three curves has a maximum breakdown voltage, which will be explained as follows.

Increasing the implantation dose of the separate p-implant will at first increase the depletion width of the vertical p-/n-well junction and thus increase the influence on the horizontal p++/n-well junction, augmenting its breakdown voltage. However, for a certain doping level, the p-implant becomes a good conductor, which leads to a shifting of the place of breakdown to the p-/n-well junction. For higher doping levels, the breakdown voltage decreases. The upper limit of the anneal time (120 minutes) needs to be imposed in order to avoid diffusing of the implant to regions under the active areas.

It is clear from FIG. 8 that the anneal time causes the breakdown voltage to increase, as long as the doping level is not too high. This is because the p-type implant depth is directly related to this anneal time: higher anneal times yield higher implant depths. Increasing the p-type implant depth increases its influence on the horizontal p++/n-well junction, augmenting in this way the breakdown voltage.

It is emphasized once more, that the method of the present invention allows the use of other process parameters to optimize the breakdown voltage of the p++/n-well junction, since the p-type implant next to said junction can be tuned independently from the other implants. Preferred implantation doses of the separate p-type implantation step (i.e. this independent p-type implant) according to the present invention are between 6×1013/cm2 and 1.2×1014/cm2 for BF2. Preferred implantation energy is between 40 keV and 60 keV for the first and second embodiment for a BF2 implant, and between 150 keV and 300 keV for the third embodiment, for a B-implant. Preferred implant doses for this B-implant are between 5×1011/cm2 and 1×1013/cm2. Preferred anneal time after the separate implantation step for all preferred embodiments is between 60 minutes and 120 minutes.

According to the second embodiment of the present invention, the size of the p-type implant does not have to be the same as the size of the field oxide on top of it. The p-type implant may be smaller than the field oxide and extend only to a given region around the p++/n-well junction. This leads to the opportunity of optimizing the size of the p-type implant in order to maximize the breakdown voltage of the junction.

### EXAMPLE 1

PDEMOS

FIG. 9 represents a PDEMOS device according to the invention. The p-type implant 46 in the n-well region 40 may be extended so that they surround the drain 43 completely (zones 46+47), thereby allowing the reduction in breakdown voltage described above. Also, both the p-type implants 46 and 47 and the p-field implant 53 can be created independently. Moreover, the separate implantation step according to either of the embodiments of the invention allows the optimization in terms of doping level, depth and width of the p-type implants 46 and 47, without deteriorating the p-field implant 53 in the p-well region 50.

### EXAMPLE 2

High voltage p++/n-well diode

A device of this type is in fact shown in FIG. 4. It comprises the p++/n-well junction, whose breakdown voltage can be limited by the surrounding p-type implant 6. To produce a device of this kind, the second embodiment of the invention is preferably used, as this gives the opportunity to optimize the size of the p-type implant 6 around the junction.

Simulation plots

The plots in FIGS. 10, 11 and 12 are derived from a 2-dimensional device simulation and illustrate some of the effects described above.

In FIG. 10, a comparison is made between a p++ region 61 having an active area width as designed of 8 m (FIGS. 10a and 10b) and a p++ region 61 having an active area width as designed of 2.2 m (FIGS. 10c and 10d), both for an implant dose of 1×1014/cm2 BF2and an implantation energy of 50 keV. FIGS. 10a and 10c show both structures, comprising the junction 60, the p++ region 61, a n-well 62, a p-type implant 63, a field oxide 67. Only half of the structure is shown in both cases. The dimensions in both directions are indicated in microns. A curve 65 shows the net doping level as a function of the distance along the cut line 64, starting from the surface. The difference in doping level between the p++ region 61, the n-well 62, and a substrate 71 can be clearly seen. In the simulation shown, the p++ contact 70 and the substrate 71 are at the same voltage of −42V with respect to the n-well 62. A curve 66 shows the electric field along the cut line 64. It can be seen that for a less wide p++ region 61, the electric field 66 underneath the junction 60 is decreased, leading to an increase in the external voltage which can be applied before breakdown occurs, and thus to an increase in breakdown voltage of such a device.

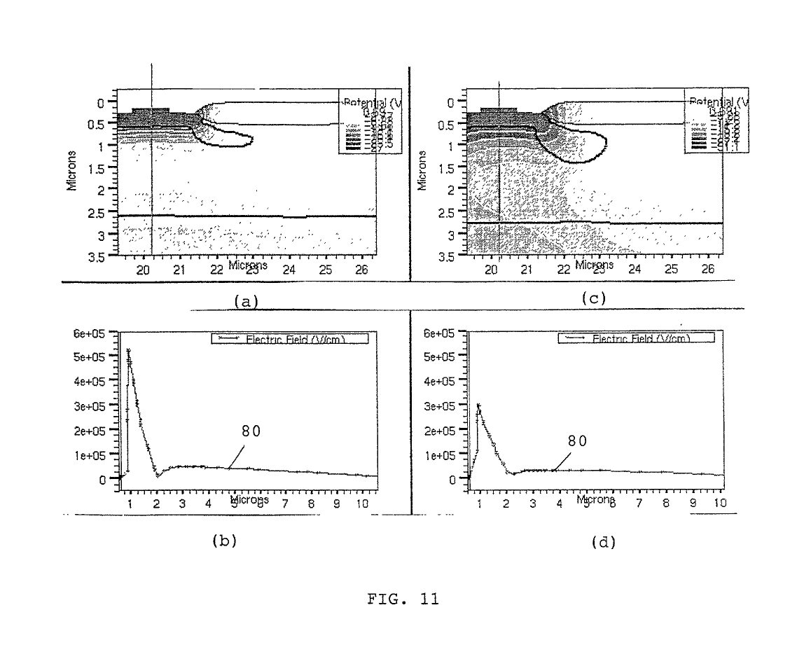

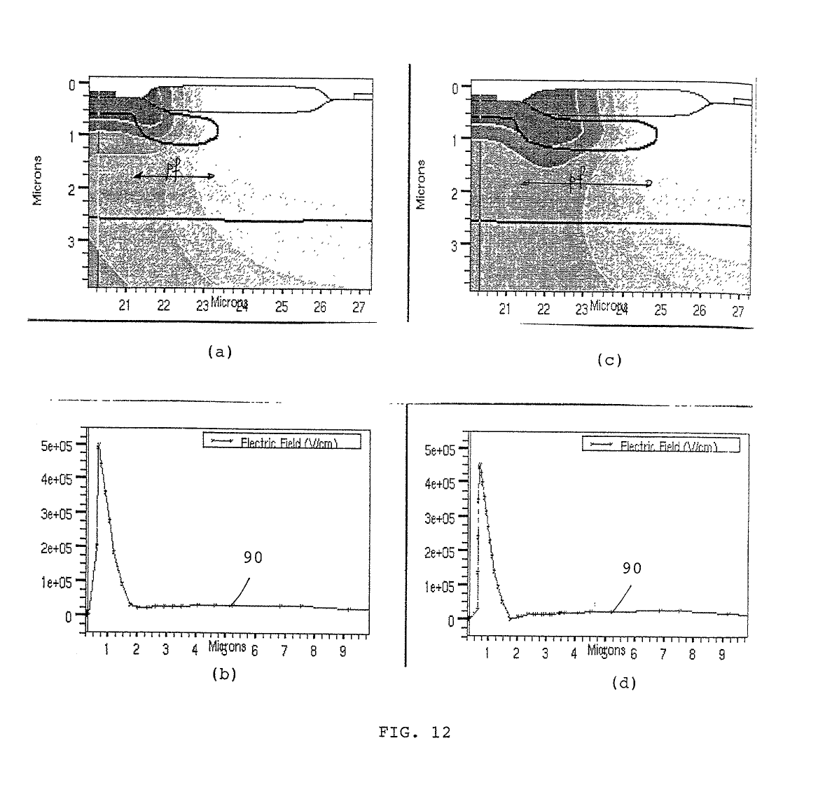

FIG. 11 illustrates in the same way the effect of the separate p-type implant depth. FIGS. 11c and 11d show the influence of a significant increase in this implant depth with respect to FIGS. 11a and 11b. All drawings in FIG. 11 are related to the p++ region 61 and the substrate 71 at a voltage of−27V with respect to the n-well region 62. FIGS. 11a and 11c are related to an implant with a dose of 6 ×1013/cm2 BF2at 50 keV. The implant in FIG. 11c is made in the same way, but a separate implantation is done after the growing of the field oxide, the latter implant being B, at 2×1012/cm2 and 200 keV. The references in FIGS. 10a and 10c are equally valid in FIGS. 11a and 11c, and 12a and 12c. A curve 80 indicates a clear drop in the electric field values, and thus an increase in breakdown voltage.

FIG. 12 illustrates in the same way the influence of the p-type implant width on the breakdown voltage. FIGS. 12a and 12b are related to an active area p-type implant definition width of 2 m, and FIGS. 12c and 12d are related to an active area p-type implant definition width of 3.5 m. All drawings in FIG. 12 are related to a BF2implant at 1×1014/cm2 and 50 keV. In all drawings of FIG. 12, the p++ region 61 and the substrate 71 are at a voltage of −65 V with respect to the n-well region 62. A curve 90 shows a decrease in the electric field for the wider implant, and thus an increase in breakdown voltage for such a device.

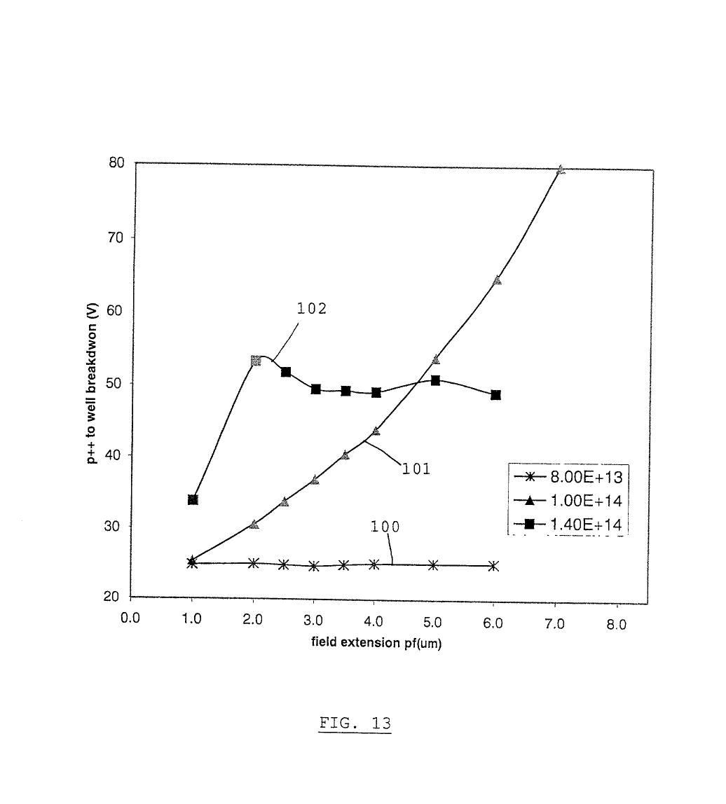

The effect of FIG. 12 is dependent upon the implantation dose, as can be seen in FIG. 13. Three curves are representing the breakdown level as a function of the p-type implant width pf, for three implantation doses: a curve 100 (8×1013/cm2), a curve 101 (1×1014/cm2), and a curve 102 (1.4×1014/cm2). The curve 101 (moderate implantation dose) shows a clear increase in the breakdown level as a function of rising pf. As the implantation dose increases, this is no longer the case, because the place of breakdown is shifted to the p-implant/n-well junction.

Thus, there has been described a new method of processing high voltage p++/n-well junction and a device produced by the method. While certain embodiments of the invention have been shown, apparently many changes and modifications may be made therein without departing from the scope of the invention. It is appreciated, therefore, that the appended claims cover any and all such changes and modifications which do not depart from the true scope of the invention.

1. A method of processing at least one high voltage p++/n-well junction on a substrate comprising at least one n-well region and at least one p-well region, the method comprising performing a p-type implantation in a zone surrounding said high voltage p++/n-well junction independently from other implantation.

2. A semiconductor device containing a high voltage p++/n-well junction, manufactured by the method comprising:
performing a p-type implantation in a zone surrounding said high voltage p++/n-well junction independently from other implantation.

3. The semiconductor device of claim 2, wherein the device comprises a P-Drain Extended MOS.

4. The semiconductor device of claim 3, wherein the P-Drain Extended MOS comprises a p++ region having an active area width of about 1.6 μm-8 μm.

5. The semiconductor device of claim 2, wherein the device comprises a high voltage floating p++/n-well diode.

6. The semiconductor device of claim 5, wherein the high voltage floating p++/n-well diode comprises a p++ region having an active area width of about 1.6 μm-8 μm.

7. A method of processing at least one high voltage p++/n-well junction on a substrate comprising at least one n-well region and at least one p-well region, the method comprising:
performing a first implantation for a p-field implant in said p-well region as well as a p-type implant around said high voltage p++/n-well junction in said n-well region; and performing a second implantation independently from the first implantation for said p-type implant around said high voltage junction in said n-well region, so as to modify the characteristics of said p-type implant in said n-well region, independently from those of said p-field implant in said p-well region.

8. The method of claim 7, further comprising:
defining at least one active area on both said n-well and p-well regions on said substrate before performing the first implantation; and
further processing said active area after performing the second implantation.

9. The method of claim 7, further comprising:
growing a field oxide on the p-type implant and the p-field implant.

10. The method of claim 9, wherein the p-type implant is wholly spatially coincident with the surface of the field oxide so that a self-aligned p-type implant is produced.

11. The method of claim 7, further comprising annealing the p-type and p-field implants after performing the second implantation.

12. The method of claim 11, wherein the annealing time is between 60 minutes and 120 minutes.

13. The method of claim 7, wherein the implant dose of said p-type implant is between 6×1013/cm2 and 1.2×1014/cm2 for a BF2 implant.

14. The method of claim 7, wherein the implant dose of said p-type implant is between 5×1011/cm2 and 1×1013/cm2 for a B (Boron) implant.

15. The method of claim 7, wherein the implantation energy of said second implantation is between 40 keV and 60 keV for a BF2 implant.

16. A semiconductor device containing a high voltage p++/n-well junction, manufactured by the method comprising:
performing a first implantation for a p-field implant in said p-well region as well as a p-type implant around said high voltage p++/n-well junction in said n-well region; and
performing a second implantation independently from the first implantation for said p-type implant around said high voltage junction in said n-well region, so as to modify the characteristics of said p-type implant in said n-well region, independently from those of said p-field implant in said p-well region.

17. The semiconductor device of claim 16, wherein the device comprises a P-Drain Extended MOS.

18. The semiconductor device of claim 17, wherein the P-Drain Extended MOS comprises a p++ region having an active area width of about 1.6 μm-8 μm.

19. The semiconductor device of claim 16, wherein the device comprises a high voltage floating p++/n-well diode.

20. The semiconductor device of claim 19, wherein the high voltage floating p++/n-well diode comprises a p++ region having an active area width of about 1.6 μm-8 μm.

21. A method of processing at least one high voltage p++/n-well junction on a substrate comprising at least one n-well region and at least one p-well region, the method comprising:
performing a first implantation for a p-field implant in said p-well region; and
performing a second implantation independently from the first implantation for said p-type implant around said high voltage junction in said n-well region.

22. The method of claim 21, further comprising:
defining at least one active area on both said n-well and p-well regions on said substrate before performing the first implantation; and
further processing said active area after performing the second implantation.

23. The method of claim 21, further comprising:
growing a field oxide on the p-type implant and the p-field implant.

24. The method of claim 23, wherein the p-type implant is wholly spatially coincident with the surface of the field oxide so that a self-aligned p-type implant is produced.

25. The method of claim 23, wherein the p-type implant is partially spatially coincident with the surface of the field oxide.

26. The method of claim 21, further comprising annealing the p-type and p-field implants after performing the second implantation.

27. The method of claim 26, wherein the annealing time is between 60 minutes and 120 minutes.

28. The method of claim 21, wherein the implant dose of said p-type implant is between 6×1013/cm2 and 1.2×1014/cm2 for a BF2implant.

29. The method of claim 21, wherein the implant dose of said p-type implant is between 5×1011/cm2 and 1×1013/cm2 for a B (Boron) implant.

30. The method of claim 21, wherein the implantation energy of said second implantation is between 40 keV and 60 keV for a BF2implant.

31. A semiconductor device containing a high voltage p++/n-well junction, manufactured by the method comprising:
performing a first implantation for a p-field implant in said p-well region; and
performing a second implantation independently from the first implantation for said p-type implant around said high voltage junction in said n-well region.

32. The semiconductor device of claim 31, wherein the device comprises a P-Drain Extended MOS.

33. The semiconductor device of claim 32, wherein the P-Drain Extended MOS comprises a p++ region having an active area width of about 1.6 μm-8 μm.

34. The semiconductor device of claim 31, wherein the device comprises a high voltage floating p++/n-well diode.

35. The semiconductor device of claim 34, wherein the high voltage floating p++/n-well diode comprises a p++ region having an active area width of about 1.6 μm-8 μm.

36. A method of processing at least one high voltage p++/n-well junction on a substrate comprising at least one n-well region and at least one p-well region, the method comprising:
performing a first implantation for a p-field implant in said p-well region;
growing a field oxide in said n-well region; and
performing a second implantation independently from the first implantation through the field oxide for said p-type implant around said high voltage junction in said n-well region.

37. The method of claim 36, further comprising:
defining at least one active area on both said n-well and p-well regions on said substrate before performing the first implantation; and
further processing said active area after performing the second implantation.

38. The method of claim 36, further comprising annealing the p-type and p-field implants after performing the second implantation.

39. The method of claim 38, wherein the annealing time is between 60 minutes and 120 minutes.

40. The method of claim 36, wherein the implant dose of said p-type implant is about 5×1011/cm2 and 1×1013/cm2.

41. The method of claim 36, wherein the implantation energy of said second implantation is between 150 keV and 300 keV for a B implant.

42. A semiconductor device containing a high voltage p++/n-well junction, manufactured by the method comprising:
performing a first implantation for a p-field implant in said p-well region;
growing a field oxide in said n-well region; and
performing a second implantation independently from the first implantation through the field oxide for said p-type implant around said high voltage junction in said n-well region.

43. The semiconductor device of claim 42, wherein the device comprises a P-Drain Extended MOS.

44. The semiconductor device of claim 43, wherein the P-Drain Extended MOS comprises a p++ region having an active area width of about 1.6 μm-8 μm.

45. The semiconductor device of claim 42, wherein the device comprises a high voltage floating p++/n-well diode.

46. The semiconductor device of claim 45, wherein the high voltage floating p++/n-well diode comprises a p++ region having an active area width of about 1.6 μm-8 μm.
